(19) United States
(12) Patent Application Publication
(10) Pub. No.: US 2004/0218369 A1
(43) Pub. Date: Nov. 4, 2004

(54) Screw-less circuit card mounting apparatus

(76) Inventor: Ronald Paul Dean, Fort Collins, CO (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/427,660

(22) Filed: Apr. 30, 2003

(51) Int. Cl. H05K 5/00; H05K 5/04; H05K 5/06

(52) U.S. Cl. 361/757

(57) ABSTRACT

Circuit card mounting apparatus eliminates the need for screw fasteners when securing a circuit card within a chassis. At least one standoff member spaces the circuit card away from a wall. At least one hook member extends away from the wall slightly farther than does the standoff member so that the thickness of a circuit card can fit between the top of the standoff member and the bottom of the hook member. The hook member is designed to pass through a corresponding clearance hole in the circuit card. A flexible tab is suspended away from the wall a sufficient distance to make contact with an edge of the circuit card when the circuit card rests on the standoff member.

### FIELD OF THE INVENTION

This invention relates generally to the field of securing circuit cards within a computer chassis or enclosure.

### BACKGROUND

In most modern computer enclosures at least one circuit card must be mounted within a chassis. For example, in personal computers and workstations, a motherboard is typically mounted to a chassis wall by passing screws through the motherboard and into a standoff member mounted to the chassis wall. The head of the screw holds the motherboard against the standoff member, preventing unwanted movement of the motherboard relative to the chassis.

### SUMMARY OF THE INVENTION

Circuit card mounting apparatus according to a preferred embodiment of the invention eliminates the need for screw fasteners when securing a circuit card within a chassis. At least one standoff member spaces the circuit card away from a wall. At least one hook member extends away from the wall slightly farther than does the standoff member so that the thickness of a circuit card can fit between the top of the standoff member and the bottom of the hook member. The hook member is designed to pass through a corresponding clearance hole in the circuit card. A flexible tab is suspended away from the wall a sufficient distance to make contact with an edge of the circuit card when the circuit card rests on the standoff member.

To mount the circuit card within the chassis without the need for screw fasteners, the circuit card is oriented so that it is substantially coplanar with the wall. The circuit card is then moved toward the wall until it can rest against the standoff member. As this is done, the hook member passes through the clearance hole in the circuit card and a perimeter surface of the circuit card presses the flexible tab toward the wall. The circuit card is then translated so that an edge of the clearance hole slides under the hook member, and the flexible tab then snaps up to retain the edge of the circuit card against the hook member. Once this has been accomplished, the top of the standoff member prevents further movement of the circuit card toward the wall. The bottom of the hook member prevents movement of the circuit card away from the wall. The sides of the hook member prevent movement of the circuit card in three of the directions parallel with the wall. And the flexible tab prevents movement of the circuit card in the fourth direction parallel with the wall, thereby keeping the circuit card engaged under the hook.

### BRIEF DESCRIPTION OF THE DRAWINGS

FIG. 1 is an oblique view of circuit card mounting apparatus according to a preferred embodiment of the invention.

FIG. 2 is a side view of the chassis of FIG. 1 illustrating a circuit card in an intermediate stage of mounting.

FIG. 3 is a simplified top view schematically illustrating the arrangement of FIG. 2.

FIG. 4 is a side view of the chassis of FIG. 1 illustrating a circuit card completely mounted thereon.

FIG. 5 is a simplified top view schematically illustrating the arrangement of FIG. 4.

FIG. 6 is an oblique close-up view illustrating the flexible tab of FIG. 1 in more detail.

FIGS. 7 and 8 are oblique and side views, respectively, of circuit card mounting apparatus according to an alternative preferred embodiment of the invention.

### DETAILED DESCRIPTION OF THE PREFERRED EMBODIMENTS

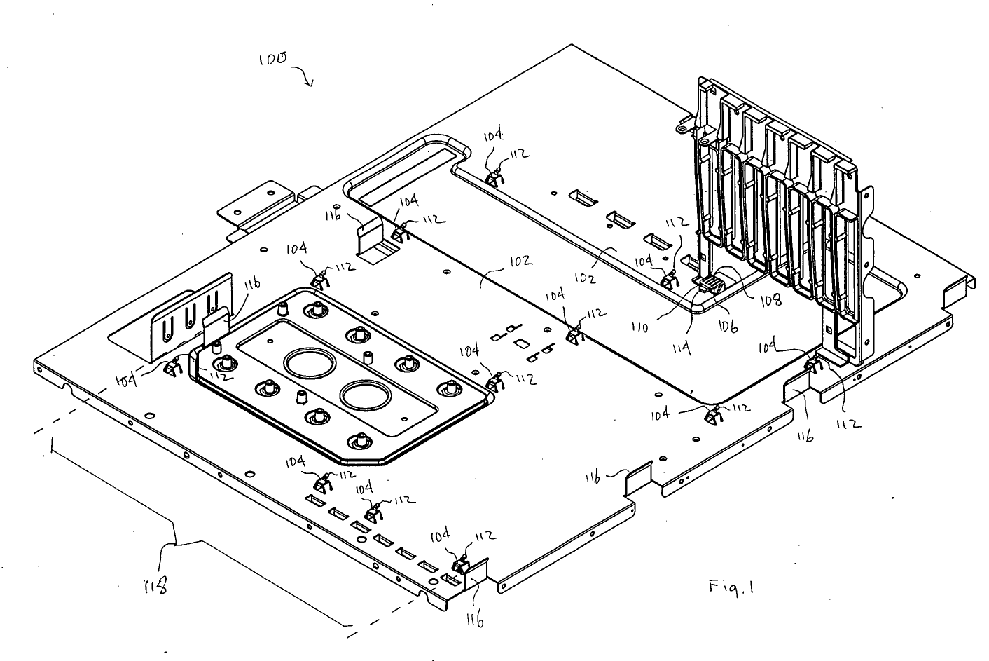

FIG. 1 illustrates circuit card mounting apparatus 100 according to a preferred embodiment of the invention. A wall 102 is provided. Wall 102 may be a chassis wall or a circuit card tray, for example. Any suitably rigid material may be used to form wall 102. For example, wall 102 may be formed from a sheet of metal such as steel or aluminum. One or more standoff members 104 are fixed to wall 102. Standoff members 104 may be integrally formed with wall 102 or may be separate pieces fixedly attached to wall 102. In the embodiment of FIG. 1, standoff members 104 take the form of plateaus that are punched out from the material of wall 102.

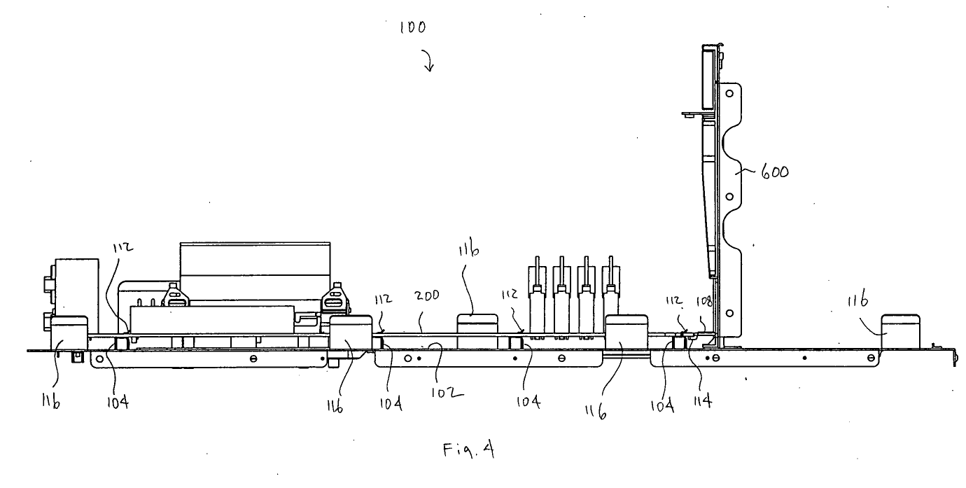

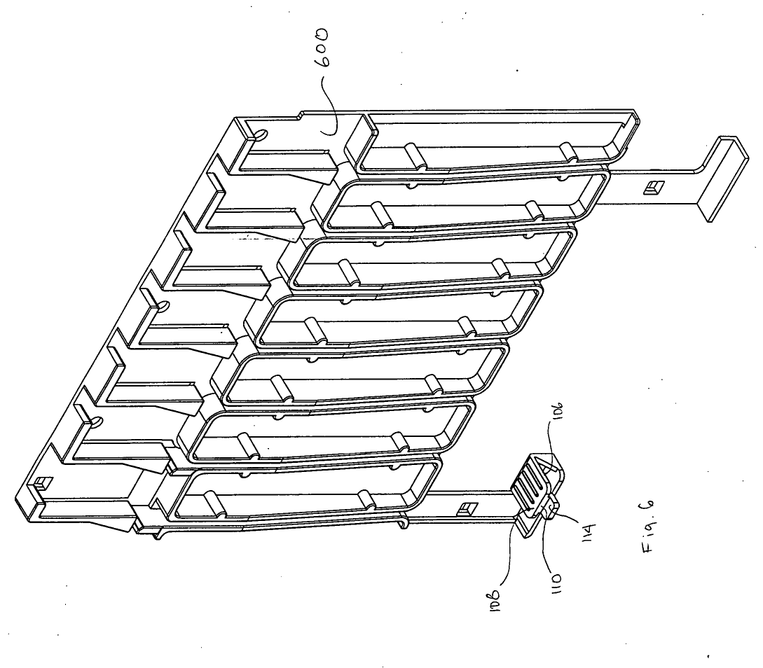

A flexible tab 106 is suspended adjacent to wall 102. Tab 106 has a top surface 108 for receiving a deflecting force exerted by circuit card 200 during mounting. Tab 106 also has a side surface 110 for engaging an edge 120 of circuit card 200 when circuit card 200 is completely mounted. Side surface 110 faces direction 500. Any suitably elastic material may be used to form tab 106, such as molded plastic or metal. A stop protrusion 114 may optionally be provided on tab 106 below side surface 110 and extending in direction 500. Stop protrusion 114 helps to ensure that side surface 110 of tab 106 engages edge 120 of circuit card 200 when tab 106 snaps up from its deflected position during mounting (to be described below). Tab 106 need not be a discrete component, but may be integrally formed with other components. For example, tab 106 maybe integrally formed with a device for aligning other circuit cards such as input/output cards as shown in FIGS. 1, 2, 4 and 6.

One or more hook members 112 extend away from wall 102 farther than do standoff members 104 by a distance approximately equal to the thickness of circuit card 200. Hook members 112 face direction 506 opposite direction 500. Hook members 112 may be discrete components or may be integrally formed with standoff members 104.

Guide members 116 may optionally be provided to help align circuit card 200 during mounting. Guide members 116 extend away from wall 102 and define a channel 118 within which circuit card 200 may be moved in directions 500, 506.

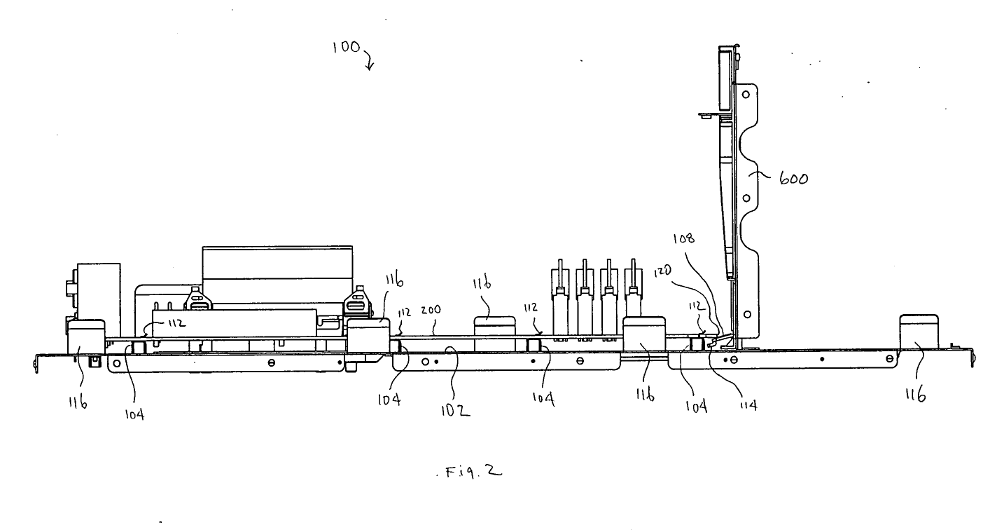

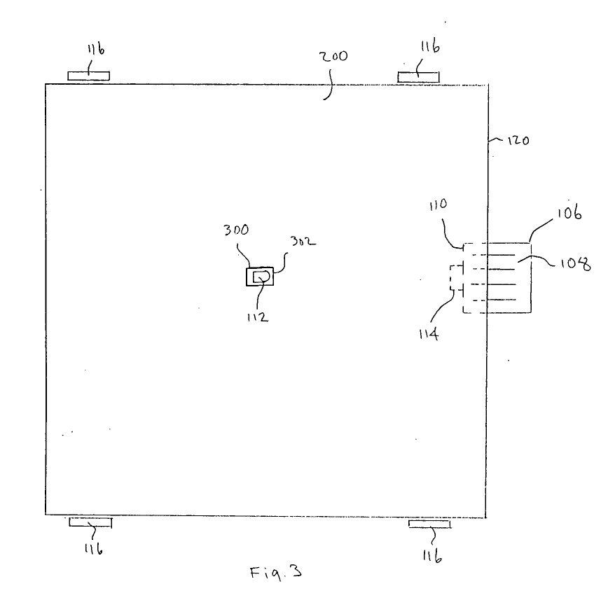

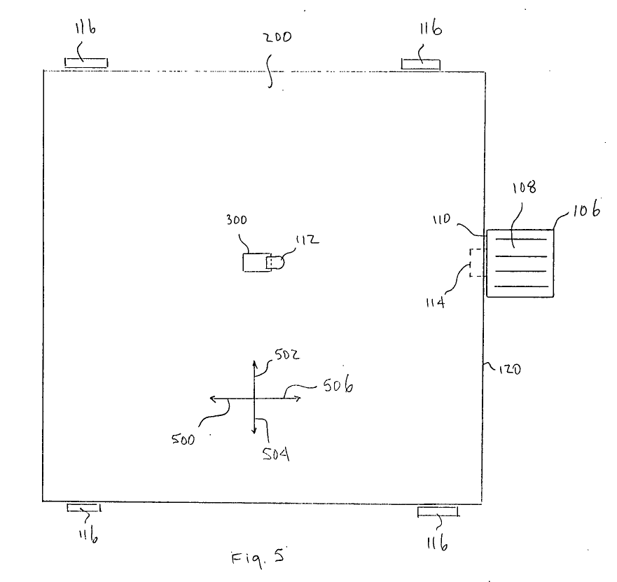

A preferred method for mounting circuit card 200 without the need for screw fasteners will now be described with reference to FIGS. 2-5. First, circuit card 200 is oriented so that it is substantially coplanar with wall 102. Circuit card 200 is then moved toward wall 102 until it can rest against the tops of standoff members 104. As this is done, hook members 112 pass through clearance holes 300 formed in circuit card 200 and a perimeter surface of circuit card 200 presses flexible tab 106 toward wall 102. Circuit card 200 is then translated in direction 500 so that edges 302 of clearance holes 300 slides under hook members 112. When edge 120 of circuit card 200 clears surface 108 of tab 106, tab 106 then snaps up. After this occurs, edge 120 of circuit card 200 is adjacent side surface 110 of tab 106. (Optional stop protrusion 114 helps to ensure alignment of edge 120 with surface 110.) Thus, side surface 110 of tab 106 prevents circuit card 200 from moving in direction 506. Hook members 112 prevent circuit card 200 from moving in directions 500, 502 and 504, as well as away from wall 102. And standoff members 104 prevent circuit card 200 from moving toward wall 102. To remove circuit card 200, tab 106 may be deflected toward wall 102 so that circuit card 200 can be moved in direction 506 to disengage it from hook members 112.

While the invention has been described in detail with reference to preferred embodiments thereof, the described embodiments have been presented by way of example and not by way of limitation. It will be understood by those skilled in the art that various changes may be made in the form and details of the described embodiments without deviating from the spirit and scope of the invention as defined by the appended claims.

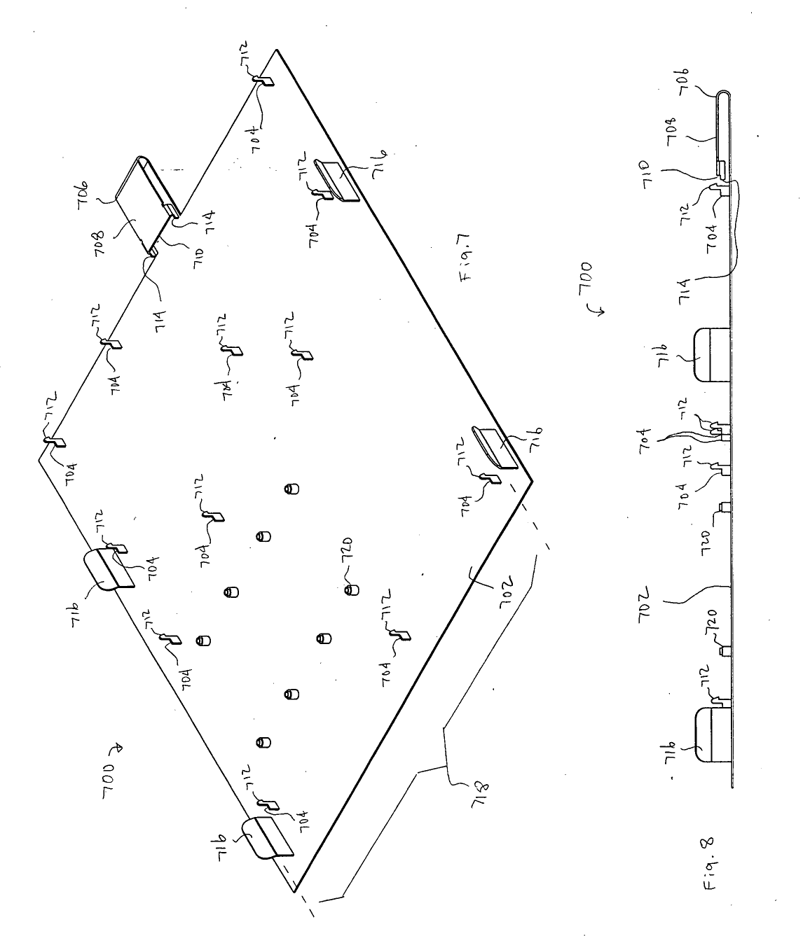

For example, in an alternative preferred embodiment 700 illustrated in FIGS. 7 and 8, a flexible tab 706 is formed by folding a portion of wall 702 back approximately 180 degrees. The bent portion includes a top surface 708 for receiving the deflecting force. The end 710 of the bent portion forms a side surface for engaging edge 110 of circuit card 200, and optional tabs 714 may serve as stop protrusions. Standoff members 704 and hook members 712 may be formed from tabs that are folded out from wall 702. Optional guide members 716 may be provided to define a channel 718 serving the same purpose as channel 118. Additional standoff members 720 may also be attached to wall 702 or 102 to provide extra support for circuit card 200.

What is claimed is:

1. Circuit card mounting apparatus, comprising:
a standoff member fixed to a wall;
a flexible tab suspended adjacent the wall, having a top surface for receiving a deflecting force and having a side surface for engaging an edge of a circuit card, the side surface facing in a first direction; and
a hook member extending away from the wall farther than the standoff member by a distance approximately equal to the thickness of a circuit card, and pointing in a second direction opposite the first direction.

2. The circuit card mounting apparatus of claim 1, wherein:
the flexible tab comprises a stop protrusion disposed below the side surface and extending in the first direction.

3. The circuit card mounting apparatus of claim 1, wherein:
the flexible tab comprises molded plastic.

4. The circuit card mounting apparatus of claim 1, wherein:
the standoff member is integrally formed with the wall.

5. The circuit card mounting apparatus of claim 1, wherein:
the hook member is integrally formed with the standoff member.

6. The circuit card mounting apparatus of claim 1, further comprising:
guide members extending away from the wall and defining a channel within which the circuit card may be moved in the first and second directions.

7. The circuit card mounting apparatus of claim 1, wherein:
the flexible tab is integrally formed with a device for aligning other circuit cards.

8. The circuit card mounting apparatus of claim 1, wherein:
the standoff member comprises a plateau punched out from the wall.

9. The circuit card mounting apparatus of claim 1, wherein:
the standoff member comprises a tab folded out from the wall.

10. The circuit card mounting apparatus of claim 1, wherein:
the wall comprises a chassis wall.

11. The circuit card mounting apparatus of claim 1, wherein:
the wall comprises a circuit card tray.

12. The circuit card mounting apparatus of claim 1, wherein:
the flexible tab comprises a portion of the wall folded back approximately 180 degrees.

13. The circuit card mounting apparatus of claim 1, wherein:
the wall comprises a sheet of metal.
